(19) United States
(12) Patent Application Publication
(10) Pub. No.: US 2005/0248420 A1
(43) Pub. Date: Nov. 10, 2005

(54) Forming integrated plural frequency band film bulk acoustic resonators

(76) Inventors: Qing Ma, San Jose, CA (US); Li-Peng Wang, San Jose, CA (US); Dong Shim, San Jose, CA (US); Valluri Rao, Saratoga, CA (US)

Correspondence Address: TROP PRUNER & HU, PC, 8554 KATY FREEWAY, SUITE 100, HOUSTON, TX, 77024, US

(21) Appl. No.: 10/841,402

(22) Filed: May 7, 2004

(51) Int. Cl. H03H 9/58

(52) U.S. Cl. 333/191

(57) ABSTRACT

Plural band film bulk acoustic resonators may be formed on the same integrated circuit using lithographic techniques. As a result, high volume production of reproducible components can be achieved, wherein the resonators, as manufactured, are designed to have different frequencies.

### BACKGROUND

This invention relates generally to front-end radio frequency filters, including film bulk acoustic resonators (FBAR).

Film bulk acoustic resonators have many advantages compared to other techniques such as surface acoustic wave (SAW) devices and ceramic filters, particularly at high frequencies. For example, SAW filters begin to have excessive insertion losses above 2.4 gigaHertz and ceramic filters are much larger in size and become increasingly difficult to fabricate at higher frequencies.

A conventional FBAR filter may include two sets of FBARs to achieve the desired filter response. The series FBARs may have one frequency and the shunt FBARs may have another frequency. Thus, for a variety of reasons, it is desirable to have filters of two or more frequency bands (termed plural frequency FBARs herein) on the same integrated circuit. A typical single band radio frequency (RF) filter has two sets of resonators, series, and shunt, with two different frequencies. In a typical cell phone, several filters for different bands are used. It is highly desirable to integrate several filters on the same silicon wafer. For example, two filters on the same silicon will need four sets of resonators with four different frequencies.

However, achieving integrated frequency FBARs is challenging using existing fabrication techniques. Those techniques are insufficiently controllable to achieve multiple thickness targets needed for reproducibly manufacturing integrated circuits with frequencies of more than one band.

Thus, there is a need for better ways to make integrated circuit FBARs having more than one frequency band.

### BRIEF DESCRIPTION OF THE DRAWINGS

FIG. 1 is an enlarged, cross-sectional view of one embodiment of the present invention at an early stage of manufacture;

FIG. 2 is an enlarged, cross-sectional view of the embodiment shown in FIG. 1 at a subsequent stage of manufacture;

FIG. 3 is an enlarged, cross-sectional view of the embodiment shown in FIG. 2 at a subsequent stage of manufacture;

FIG. 4 is an enlarged, top plan view of the embodiment shown in FIG. 3 in accordance with one embodiment of the present invention;

FIG. 5 is an enlarged, cross-sectional view of one embodiment of the present invention prior to completion in accordance with one embodiment of the present invention; and

FIG. 6 is an enlarged, cross-sectional view of the embodiment shown in FIG. 5 after completion in accordance with one embodiment of the present invention.

### DETAILED DESCRIPTION

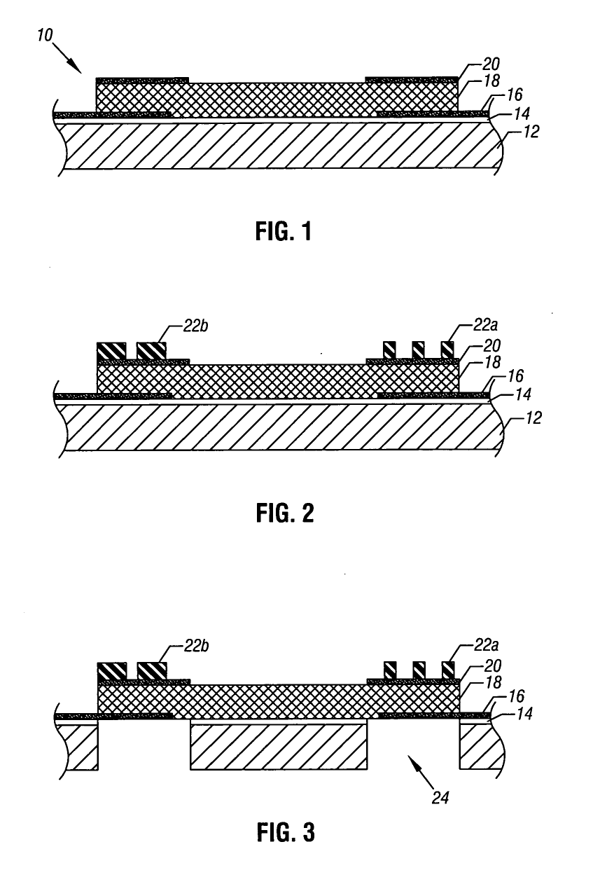

Referring to FIG. 1, a film bulk acoustic resonator (FBAR) 10 may include an upper electrode 20 and a bottom electrode 16 sandwiching a piezoelectric layer 14. That structure may be formed over a dielectric layer 14 formed on a substrate 12. In accordance with one embodiment of the present invention, the dielectric layer 14 may be formed of silicon dioxide. The bottom electrode 16 may be formed of material such as aluminum, molybdenum, platinum, or tungsten, for example.

The piezoelectric layer 18 may be formed of aluminum nitride, lead zirconium titanate (PZT), or zinc oxide, to mention a few examples. The upper electrode 20 may be formed of the same materials as the bottom electrode 16.

While a bulk micromachined fabrication technique is set forth below, the present invention is equally applicable to surface micromachined FBAR processes as well.

The structure shown in FIG. 1 is covered with a layer 22 of a modulating material. The modulating material is a material that has a high acoustic quality factor such as aluminum oxide, polysilicon, molybdenum, or tungsten.

The deposited layer 22 is then patterned to form the structure shown in FIG. 2. The patterning may form a series of stripes including stripes 22a of one width (horizontal) and stripes 22b of another width. The pattern of stripes 22 may be chosen to determine the frequency of the resulting FBAR.

Finally, referring to FIG. 3, a backside silicon etch may be utilized to form the trenches 24 and resulting membranes over the trenches 24.

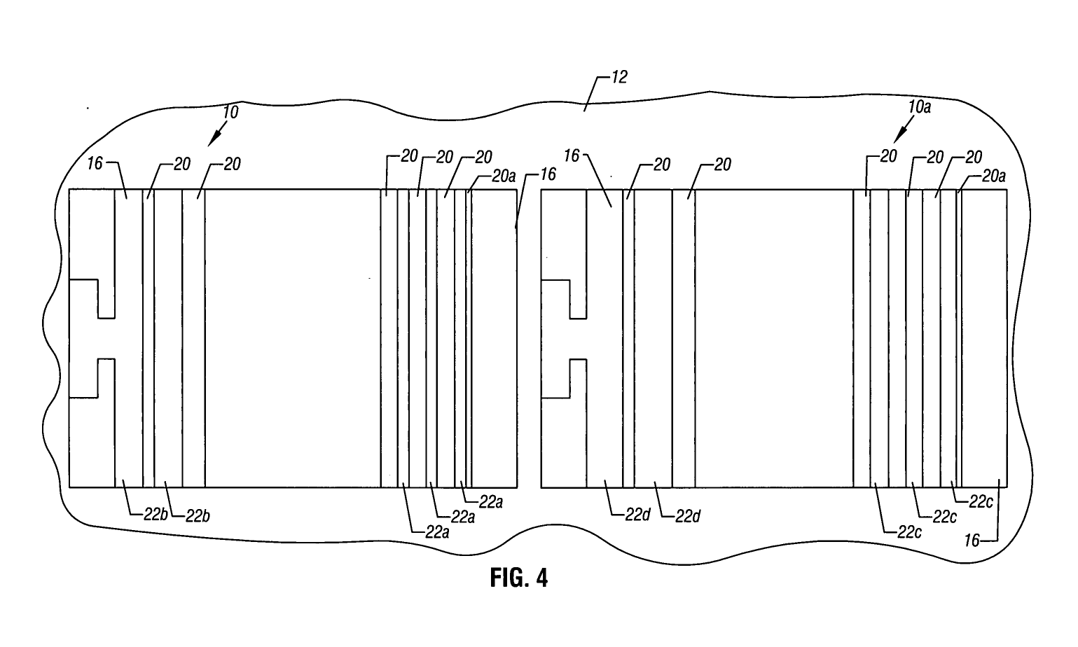

As shown in FIG. 4, a first FBAR 10 may have a bottom electrode 16 that forms contact surfaces for making electrical connections to the FBAR 10. The stripes 22b may extend completely across the FBAR, as may the stripes 22a. However, the spacing between the stripes 22a may be different, as well as their widths, in one embodiment.

The stripes 22 may be formed using conventional lithographic techniques involving patterning and etching. Thus, extremely tight control may be had over the precise nature of the modulating material 22.

A second FBAR 10a may be formed on the same substrate 12. It may operate over a different frequency because its stripes 20c and 20d are dimensionally different from the stripes 20a and 20b of the FBAR 10.

Lithographically patterned features, such as those shown in FIG. 3, on top of FBAR membranes create resonance modes with frequencies governed by the dimension and shape of those features. Thus, resonators of various frequencies may be produced using membranes of the same thickness. In other words, on the same integrated circuit, FBARs with different frequencies, called plural frequency FBARs, can be produced using conventional integrated circuit fabrication techniques which are highly reproducible, in some embodiments of the present invention.

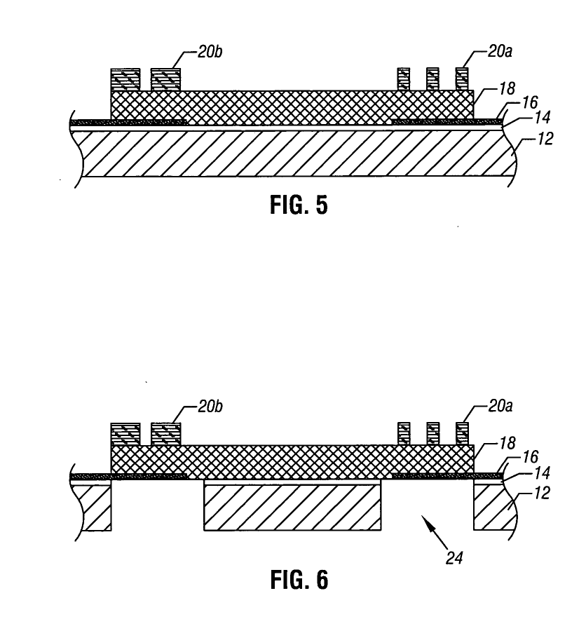

Referring to FIG. 5, in accordance with another embodiment of the present invention, the upper electrode 20 of the previous embodiment may be dispensed with and may be formed as a series of stripes 20a and 20b of modulating material. In other words, the modulating material not only sets the frequency of the FBAR, but also provides its upper electrode 20. In one embodiment, a layer 20 of material, which may be made of any of the material useful in forming electrodes in FBARs, may have its (vertical) thickness adjusted to provide the desired frequency. Thus, the pattern and shape of the stripes 20a and 20b may be varied to achieve the desired frequency performance. The spacing, size, and/or thickness in the vertical direction of the stripes 20 may be varied to achieve the desired performance in some embodiments.

Referring to FIG. 6, a cavity 24 may be defined through the substrate 12 to create the FBAR membrane structure. While stripes have been described for creating the desired frequency performance, other geometric shapes may be utilized in other embodiments. Thus, the present invention is not limited to any specific geometry for the feature that enables the selection of the FBAR frequency. Also, FBARs of any number of different frequencies may be formed on the same integrated circuit.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
lithographically defining at least two film bulk acoustic resonators of different frequencies on the same integrated circuit.

2. The method of claim 1 including forming a bottom electrode over a substrate.

3. The method of claim 2 including forming a piezoelectric material over said bottom electrode.

4. The method of claim 3 including forming an upper electrode over said piezoelectric material.

5. The method of claim 4 including forming a modulating material over said upper electrode to set the frequency of each of said resonators.

6. The method of claim 4 including forming said upper electrode to set the frequency of each of said resonators.

7. The method of claim 6 including forming a resonator with different upper electrode vertical heights on the same integrated circuit.

8. The method of claim 1 including forming at least two resonators having different patterns of stripes over their upper electrodes to have different frequencies.

9. The method of claim 1 including depositing a material having a high acoustic quality factor over said upper electrode.

10. The method of claim 1 including lithographically patterning the upper electrodes of two resonators to form two resonators of different frequencies.

11. The method of claim 1 including varying a characteristic of an upper electrode of each of said resonators to form resonators of two different frequencies.

12. A method comprising:
forming a first film bulk acoustic resonator on an integrated circuit, said first film bulk acoustic resonator having a first frequency; and
forming a second film bulk acoustic resonator on said integrated circuit at a second frequency, different from said first frequency, using lithography and patterning to distinguish said resonators.

13. The method of claim 12 including forming a bottom electrode over a substrate, a piezoelectric material over said bottom electrode, and an upper electrode over said piezoelectric material for each resonator.

14. The method of claim 13 including forming a modulating material over said upper electrode to set the frequency of each of said two resonators.

15. The method of claim 13 including forming said upper electrode in a way to set the frequency of each of said two resonators.

16. The method of claim 15 including varying the vertical height of said upper electrodes of said resonators to produce two resonators of different frequencies.

17. The method of claim 13 including forming stripes of modulating material of different widths over the upper electrodes to set the frequency band of each of said two film bulk acoustic resonators.

18. The method of claim 12 including varying a characteristic of the upper electrode of each of said resonators to form said resonators of two different frequencies.

19. An integrated circuit comprising:
a first film bulk acoustic resonator operating at a first frequency;
a second film bulk acoustic resonator operating at a second frequency; and
said first and second resonators having different upper electrode structure patterning to set different frequencies for each of said resonators.

20. The circuit of claim 19 wherein said first and second resonators have upper electrodes which are patterned differently to vary the frequency between said resonators.

21. The circuit of claim 19 wherein said structure includes a modulating material, each of said resonators including an upper electrode and said modulating material being formed over said upper electrodes, said modulating material being formed in a first pattern on a first resonator and a second pattern on the second resonator to form resonators of different frequencies.

22. The circuit of claim 19 wherein said first and second resonators have electrodes with different thicknesses.

23. The circuit of claim 19 wherein said resonators include upper electrodes formed as a series of parallel stripes.

24. The circuit of claim 23 wherein said stripes have a varied thickness to set a frequency for said resonator.
